(19) United States
(12) Patent Application Publication
(10) Pub. No.: US 2024/0071967 A1
(43) Pub. Date: Feb. 29, 2024

(54) SEMICONDUCTOR DIE INCLUDING AN ASYMMETRIC PAD ARRAYS, A SEMICONDUCTOR DIE STACK INCLUDING THE SEMICONDUCTOR DIE, AND A HIGH BANDWIDTH MEMORY INCLUDING THE SEMICONDUCTOR DIE STACK

(71) Applicant: SK hynix Inc., Gyeonggi-do (KR)

(72) Inventor: Choung Ki SONG, Gyeonggi-do (KR)

(21) Appl. No.: 18/103,494

(22) Filed: Jan. 31, 2023

(30) Foreign Application Priority Data
Aug. 24, 2022 (KR) 10-2022-0106083

(51) Int. Cl. H01L 23/00; H01L 21/66; H01L 23/48; H10B 80/00

(52) U.S. Cl. CPC H01L 24/08; H01L 22/32; H01L 23/481; H01L 24/06; H01L 24/16; H01L 24/80; H10B 80/00; H01L 2224/06515; H01L 2224/08145; H01L 2224/16145; H01L 2224/16225; H01L 2224/80379

(57) ABSTRACT

A semiconductor die stack includes a lower semiconductor die and an upper semiconductor die. The upper semiconductor die includes a first upper bonding pad disposed in a first upper bonding pad region; and a second upper bonding pad disposed in a second upper bonding pad region. The lower semiconductor die includes a first lower bonding pad disposed in a first lower bonding pad region; and a second lower bonding pad disposed in a second lower bonding pad region. The second upper bonding pad and the first lower bonding pad are vertically aligned and directly bonded to each other. The second upper bonding pad and the first lower bonding pad are not electrically connected to an upper electrical circuit in the upper semiconductor die, and electrically connected to a lower electrical circuit in the lower semiconductor die.

The present application claims priority under 35 U.S.C. § 119 to Korean Patent Application No. 10-2022-0106083, filed on Aug. 24, 2022 in the Korean Intellectual Property Office, which is incorporated herein by reference in its entirety.

### BACKGROUND

### 1. Field

Various embodiments of the preset invention disclosure relate to a semiconductor die, a semiconductor die stack including the semiconductor die, and a memory including the semiconductor die stack.

### 2. Description of the Related Art

Recently, high bandwidth memory including a number of stacked semiconductor die stacks has been proposed and is the subject of extensive development efforts.

### SUMMARY

An embodiment of the present invention disclosure is directed to a semiconductor die that includes an asymmetrical bonding pad array.

Another embodiment of the present invention disclosure is directed to a semiconductor die stack that includes the semiconductor die.

Yet another embodiment of the present invention disclosure is directed to a memory stack that includes the semiconductor die stack.

A semiconductor die stack in accordance with an embodiment of the present invention disclosure may include a lower semiconductor die and an upper semiconductor die stacked in a face-to-face form. The upper semiconductor die includes a first upper bonding pad disposed in a first upper bonding pad region adjacent to a first edge side of the upper semiconductor die; and a second upper bonding pad disposed in a second upper bonding pad region adjacent to a second edge side of the upper semiconductor die, the first edge side and the second edge side of the upper semiconductor die being opposite to each other. The lower semiconductor die includes a first lower bonding pad disposed in a first lower bonding pad region adjacent to a first edge side of the lower semiconductor die; and a second lower bonding pad disposed in a second lower bonding pad region adjacent to a second edge side of the lower semiconductor die, the first edge side and the second edge side of the lower semiconductor die being opposite to each other. The second upper bonding pad and the first lower bonding pad are vertically aligned and directly bonded to each other. The second upper bonding pad and the first lower bonding pad are not electrically connected to an upper electrical circuit in the upper semiconductor die, and electrically connected to a lower electrical circuit in the lower semiconductor die.

A memory stack in accordance with an embodiment of the present invention disclosure may includes a plurality of semiconductor die stacks and inter-stack bumps between the semiconductor die stacks. Each of the plurality of semiconductor die stacks includes an upper semiconductor die and a lower semiconductor die bonded in a face-to-face form. The upper semiconductor die includes an upper common pad disposed in an upper common pad region disposed in a central region of a front surface of the upper semiconductor die; a first upper bonding pad disposed in a first upper bonding pad region adjacent to a first edge side of the upper semiconductor die; and a second upper bonding pad disposed in a second upper bonding pad region adjacent to a second edge side of the upper semiconductor die. The lower semiconductor die includes a lower common pad disposed in a lower common pad region disposed in a central region of a front surface of the lower semiconductor die; a first lower bonding pad disposed in a first lower bonding pad region adjacent to a first edge side of the lower semiconductor die; and a second lower bonding pad disposed in a second lower bonding pad region adjacent to a second edge side of the lower semiconductor die. The upper common pad and the lower common pad are vertically aligned to be directly bonded with each other. The first upper bonding pad and the second lower bonding pad are vertically aligned to be directly bonded with other. The second upper bonding pad and the first lower bonding pad are vertically aligned to be directly bonded with each other. The upper common pad of a lower semiconductor die stack disposed at a lower position of the semiconductor die stacks and the lower common pad of an upper semiconductor die stack disposed at an upper position of the semiconductor die stacks are electrically connected with each other through an inter-stack bump. The first upper bonding pad of the lower semiconductor die stack disposed at the lower position of the semiconductor die stacks and the second lower bonding pad of the upper semiconductor die tack disposed at the upper position of the semiconductor die stacks are not electrically connected with each other.

A high bandwidth memory in accordance with an embodiment of the present invention disclosure may include an interposer; and a plurality of memory stacks and a processing unit mounted on the interposer. Each of the plurality of memory stacks includes a base die; and a semiconductor die stack stacked on the base die. The semiconductor die stack includes an upper semiconductor die and a lower semiconductor die boded bonded in a face-to-face form. The upper semiconductor die includes a first upper bonding pad disposed in a first upper bonding pad region adjacent to a first edge side of the upper semiconductor die; and a second upper bonding pad disposed in a second upper bonding pad region adjacent to a second edge side of the upper semiconductor die. The lower semiconductor die includes a first lower bonding pad disposed in a first lower bonding pad region adjacent to a first edge side of the lower semiconductor die; and a second lower bonding pad disposed in a second lower bonding pad region adjacent to a second edge side of the lower semiconductor die. The first upper bonding pad and the second lower bonding pad are vertically aligned to be directly bonded with each other. The second upper bonding pad and the first lower bonding pad are vertically aligned to be directly bonded with each other. The first upper bonding pad and the second lower bonding pad are electrically connected to an upper electrical circuit in the upper semiconductor die, and are not electrically connected to a lower electrical circuit in the lower semiconductor die. The second upper bonding pad and the first lower bonding pad are not electrically connected to the upper electrical circuit in the upper semiconductor die and are electrically connected to the lower electrical circuit in the lower semiconductor die.

A method of testing a semiconductor die stack which includes an upper semiconductor die and a lower semiconductor die stacked in a face-to-face form, wherein the upper semiconductor die includes an upper common pad disposed in an upper common pad region; a first upper bonding pad disposed in a first upper bonding pad region; and a second upper bonding pad disposed in a second upper bonding pad region, wherein the lower semiconductor die includes a lower common pad disposed in a lower common pad region; a first lower bonding pad disposed in a first lower bonding pad region; and a second lower bonding pad disposed in a second lower bonding pad region, wherein the lower common pad and the upper common pad are directly bonded with each other, wherein the first upper bonding pad and the second lower bonding pad are directly bonded with other, wherein the second upper bonding pad and the first lower bonding pad are directly bonded with other, wherein the method includes providing a common signal to the upper and lower common pads; providing a first signal to the first upper bonding pad and the second lower bonding pad; and providing a second signal to the second upper bonding pad and the first lower bonding pad. The first signal includes a first semiconductor chip selection signal for selecting and activating the upper semiconductor die. The second signal includes a second semiconductor chip selection signal for selecting and activating the lower semiconductor die.

A method of testing a semiconductor die stack which includes an upper semiconductor die and a lower semiconductor die stacked in a face-to-face form, wherein the upper semiconductor die includes an upper common pad disposed in an upper common pad region; a first upper bonding pad disposed in a first upper bonding pad region; and a second upper bonding pad disposed in a second upper bonding pad region, wherein the lower semiconductor die includes a lower common pad disposed in a lower common pad region; a first lower bonding pad disposed in a first lower bonding pad region; and a second lower bonding pad disposed in a second lower bonding pad region, wherein the lower common pad and the upper common pad are directly bonded to each other; wherein the first upper bonding pad and the second lower bonding pad are directly bonded to each other; and wherein the second upper bonding pad and the first lower bonding pad are directly bonded to each other, wherein the method includes providing a common signal to the upper and lower common pads; providing a first signal to the first upper bonding pad and the second lower bonding pad; and providing a second signal to the second upper bonding pad and the first lower bonding pad, wherein the first signal includes a first data signal for delivering data of the upper semiconductor die, and wherein the second signal includes a second data signal for delivering data of the lower semiconductor die.

### BRIEF DESCRIPTION OF THE DRAWINGS

FIG. 1A is a perspective view illustrating an upper semiconductor die and a lower semiconductor die according to an embodiment of the present invention disclosure. FIG. 1B is a perspective view illustrating bonding the upper semiconductor die and the lower semiconductor die in a face-to-face form.

FIG. 2A is a side view schematically illustrating a semiconductor die stack 100A according to an embodiment of the present invention disclosure, FIG. 2B is an enlarged view of an area A1 of FIG. 2A, and FIG. 2C is an enlarged view of an area A2 and an area A3 of FIG. 2A.

FIG. 3A is a side view schematically illustrating a semiconductor die stack according to an embodiment of the present invention disclosure, and FIG. 3B is an enlarged view of the area A4 and area A5 of FIG. 3A.

FIG. 4A is a side view schematically illustrating a semiconductor die stack according to an embodiment of the present invention disclosure, and FIG. 4B is an enlarged view of the area A6 and area A7 of FIG. 4A.

FIGS. 5A to 5C are views illustrating a method of testing the upper semiconductor die and the lower semiconductor die of the semiconductor die stacks according to an embodiment of the present invention disclosure.

FIGS. 6A to 6C are views illustrating a method of testing the upper semiconductor die and lower semiconductor die of the semiconductor die stacks according to an embodiment of the present invention disclosure.

FIGS. 7A to 7C are views schematically illustrating high bandwidth memories according to embodiments of the present invention disclosure.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

It will be understood that, although the terms “first” and/or “second” may be used herein to describe various elements, these elements should not be limited by these terms. These terms are only used to distinguish one element, from another element. For instance, a first element discussed below could be termed a second element without departing from the teachings of the present invention disclosure. Similarly, the second element could also be termed the first element.

Other expressions that explain the relationship between elements, such as “between”, “directly between”, “adjacent to” or “directly adjacent to” should be construed in the same way. The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

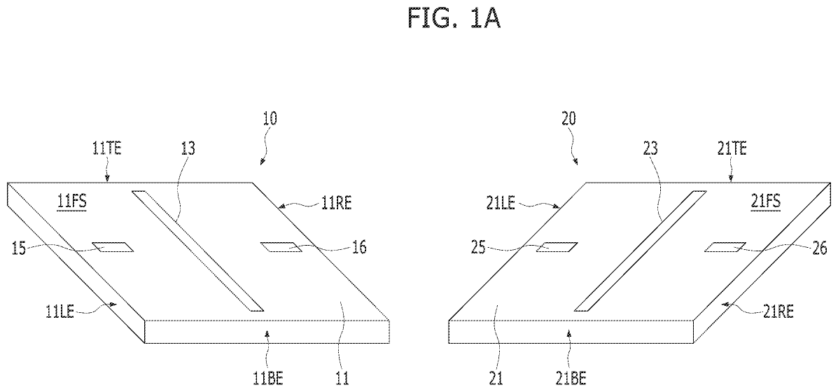

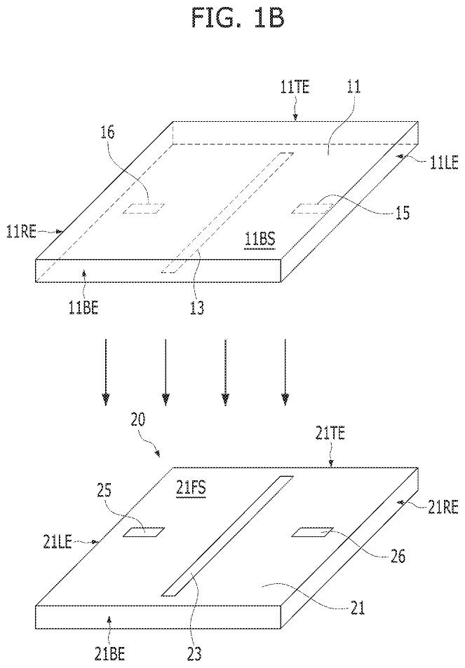

FIG. 1A is a perspective view illustrating an upper semiconductor die 10 and a lower semiconductor die 20 according to an embodiment of the present invention disclosure. FIG. 1B is a perspective view illustrating bonding the upper semiconductor die 10 and the lower semiconductor die 20 in a face-to-face form. Referring to FIG. 1A, an upper semiconductor die 10 according to an embodiment of the present invention disclosure may include upper bonding pad regions 13, 15, and 16 disposed on an upper front surface 11FS of an upper body 11 of the upper semiconductor die 10. A lower semiconductor die 20 may include lower bonding pad regions 23, 25, and 26 disposed on a lower front surface 21FS of a lower body 21 of the lower semiconductor die 20.

The upper body 11 may have four upper edge sides 11TE, 11BE, 11LE, and 11RE, and the lower body 21 may have four lower edge sides 21TE, 21BE, 21LE, and 21RE. For example, the upper body 11 may have and upper top edge side 11TE, an upper bottom edge side 11BE, an upper left edge side 11LE, and an upper right edge side 11RE, and the lower body 21 may have a lower top edge side 21TE, a lower bottom edge side 21BE, a lower left edge side 21LE, and a lower right edge side 21RE. The upper top edge side 11TE may be opposite to the upper bottom edge side 11BE, and the lower top edge side 21TE may be opposite to the lower bottom edge side 21BE. The upper left edge side 11LE may be opposite to the upper right edge side 11RE, and the lower left edge side 21LE may be opposite to the lower right edge side 21RE.

The upper semiconductor die 10 may include an upper common bonding pad region 13, a first upper bonding pad region 15, and a second upper bonding pad region 16 disposed on the upper front surface 11FS of the upper body 11. The lower semiconductor die 20 may include a lower common bonding pad region 23, a first lower bonding pad region 25, and a second lower bonding pad region 26 disposed on the lower front surface 21FS of the lower body 21.

The upper and lower common bonding pad regions 13 and 23 may be disposed in a central region on the upper and lower front surfaces 11FS and 21FS of the upper and lower semiconductor dies 10 and 20 to extend along a column direction in an elongated shape, respectively. The first upper and lower bonding pad regions 15 and 25 may be disposed adjacent to upper and lower first edge sides (e.g., upper and lower left edge sides 11LE and 21LE) of the upper and lower bodies 11 and 21 of the upper and lower semiconductor dies 10 and 20, respectively. The second upper and lower bonding pad regions 16 and 26 may be disposed adjacent to the upper and lower second edge sides (e.g., upper and lower right edge sides, 11RE and 21RE) of the upper and lower bodies 11 and 21 of the upper and lower semiconductor dies and 20, respectively. The upper and lower first edge sides and the upper and lower second edge sides may be opposite to each other. Accordingly, the first upper bonding pad region 15 and the second upper bonding pad region 16 may include first and second upper bonding pads arranged in a line symmetric form, and the first lower bonding pad region 25 and the second lower bonding pad region 26 may include first and second lower bonding pads arranged in a line symmetric form. In another embodiment, the upper first edge side of the upper body 11 of the upper semiconductor die 10 may be one of the four upper edge sides 11TE, 11BE, 11LE, and 11RE, and the upper second edge side of the upper body 11 of the upper semiconductor die may be another one of the four upper edge sides 11BE, 11TE, 11RE, and 11LE opposite to the upper first edge side. In another embodiment, the lower first edge side of the lower body 21 of the lower semiconductor die 20 may be one of the four lower edge sides 21TE, 21BE, 21LE, and 21RE, and the lower second edge side of the lower body 21 of the lower semiconductor die 20 may be another one of the four lower edge sides 21BE, 21TE, 21RE, and 21LE opposite to the upper first edge side.

Referring to FIG. 1, the upper semiconductor die 10 and the lower semiconductor die 20 may be bonded to each other in the face-to-face form that the upper front surface 11FS of the upper body 11 of the upper semiconductor die 10 and the lower front surface 21FS of the lower body 21 of the lower semiconductor die 20 may be faced each other. For example, the upper top edge side 11TE of the upper semiconductor die 10 and the lower top edge side 21TE of the lower semiconductor die 20 may be adjacent to each other, the upper bottom edge side 11BE of the upper semiconductor die 10 and the lower bottom edge side 21BE of the lower semiconductor die 20 may be adjacent to each other, the upper left edge side 11LE of the upper semiconductor die 10 and the lower right edge side 21RE of the lower semiconductor die 20 may be adjacent to each other, and the upper right edge side 11RE of the upper semiconductor die 10 and the lower left edge side 21LE of the lower semiconductor die 20 may be adjacent to each other. The upper semiconductor die 10 and the lower semiconductor die 20 may be bonded so that the upper common bonding pad region 13 of the upper semiconductor die 10 and the lower common bonding pad region 23 of the lower semiconductor die 20 may face each other, the first upper bonding pad region 15 of the upper semiconductor die 10 and the second lower bonding pad region 26 of the lower semiconductor die 20 may face each other, and the second upper bonding pad region 16 of the upper semiconductor die 10 and the first lower bonding pad region 25 of the lower semiconductor die 20 may face each other. Accordingly, upper common bonding pads in the upper common bonding pad region 13 of the upper semiconductor die 10 and lower common bonding pads in the lower common bonding pad region 23 of the lower semiconductor die 20 may be bonded to each other, first upper bonding pads in the first upper bonding pad region 15 of the upper semiconductor die 10 and second lower bonding pads in the second lower bonding pad region 26 of the lower semiconductor die 20 may be bonded to each other, and second upper bonding pads in the second upper bonding pad region 16 of the upper semiconductor die 10 and first lower bonding pads in the first lower bonding pad region 25 of the lower semiconductor die 20 may be bonded to each other.

In another embodiment, the upper common bonding pad region 13 of the upper semiconductor die 10 may be disposed on the upper front surface 11FS of the upper body 11 of the upper semiconductor die to extend along a row direction in an elongated form, and the lower common bonding pad region 23 of the lower semiconductor die 20 may be disposed on the lower front surface 21FS of the lower body 21 of the lower semiconductor die 20 to extend along the low direction in an elongated form.

In the embodiments of the present invention disclosure, the upper and lower bonding pads in the upper and lower common bonding pad regions 13 and 23 may be operating bonding pads or common test bonding pads. The first and second upper and lower bonding pads in the first and second upper bonding pad regions 15 and 16 and the first and second lower bonding pad regions 25 and 26 may be test bonding pads for testing the upper and lower semiconductor dies 10 and 20.

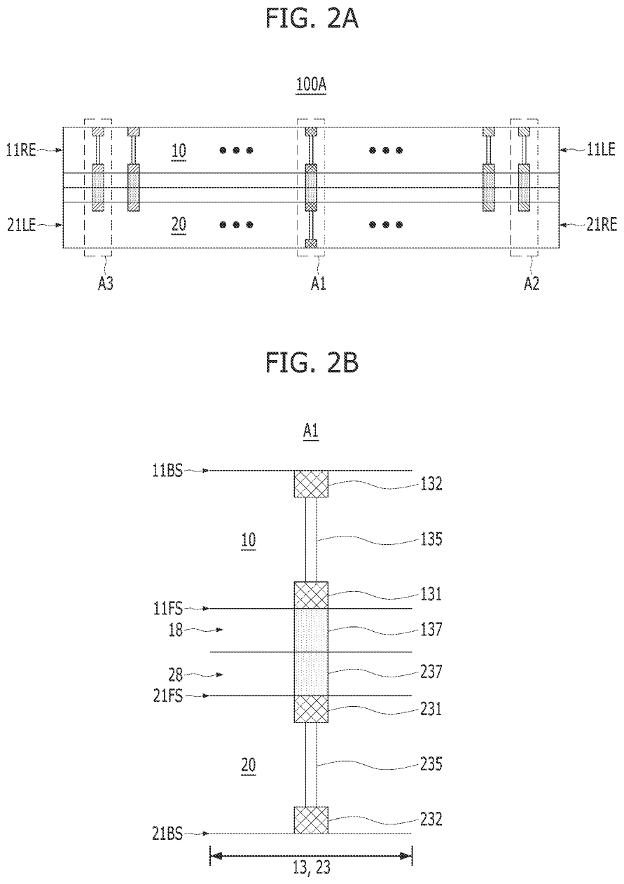

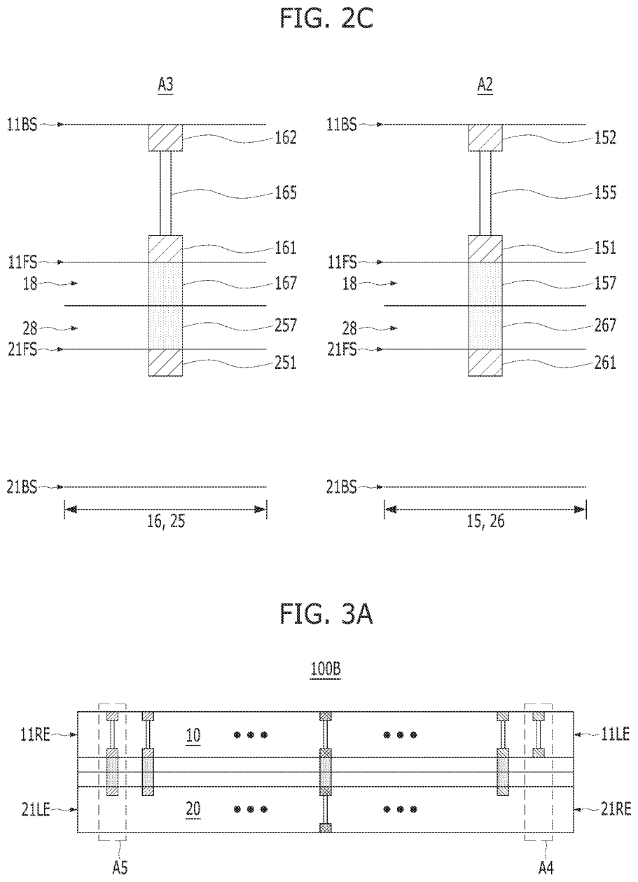

FIG. 2A is a side view schematically illustrating a semiconductor die stack 100A according to an embodiment of the present invention disclosure, FIG. 2B is an enlarged view of an area A1 of FIG. 2A, and FIG. 2C is an enlarged view of an area A2 and an area A3 of FIG. 2A. The area A1 shows that the upper common bonding pad region 13 of the upper semiconductor die 10 and the lower common bonding pad region 23 of the lower semiconductor die 20 are bonded to each other, the area A2 shows that the second upper bonding pad region 16 of the upper semiconductor die 10 and the first lower bonding pad region 25 of the lower semiconductor die 20 are bonded to each other, and the area A3 shows that the first upper bonding pad region 15 of the upper semiconductor die 10 and the second lower bonding pad region 26 of the lower semiconductor die 20 are bonded to each other.

Referring to FIGS. 2A to 2C, a semiconductor die stack 100A according to an embodiment of the present invention disclosure may include the lower semiconductor die 20 and the upper semiconductor die 10 bonded to and stacked on the lower semiconductor die 20. The lower semiconductor die 20 and the upper semiconductor die 10 may be bonded to each other and stacked in the face-to-face form in which the upper and lower front surfaces 11FS and 21FS face each other. That is, the upper semiconductor die 10 and the lower semiconductor die 20 may be bonded to each other so that the upper first edge side (e.g., the upper left edge side 11LE) of the upper semiconductor die 10 and the lower second edge side (e.g., the lower right edge side 21RE) of the lower semiconductor die 20 may be vertically aligned to each other, and the upper second edge side (e.g., the upper right edge side 11RE) of the upper semiconductor die 10 and the lower first edge side (e.g., the lower left edge side 21LE) of the lower semiconductor die 20 may be vertically aligned. In another embodiment, the upper first edge side of the upper semiconductor die 10 may be one of the upper top edge side 11TE, the upper bottom edge side 11BE, and the upper right edge side 11RE, and the upper second edge side of the upper semiconductor die 10 may be one of the upper bottom edge side 11BE, the upper top edge side 11TE, and the upper left edge side 11LE opposite to the upper first edge side of the upper semiconductor die 10. The lower second edge side of the lower semiconductor die 20 may be one of the lower bottom edge side 21BE, the lower top edge side 21TE, and the lower left edge side 21LE, and the lower first edge side of the lower semiconductor die may be one of the lower top edge side 21TE, the lower bottom edge side 21BE, and the lower right edge side 21RE opposite to the lower second edge side of the lower semiconductor die 20.

Referring to FIGS. 2A and 2B, the upper semiconductor die 10 may include an upper common top metal pattern 131, an upper common back-side pad 132, an upper common through-via 135, an upper common bonding pad 137, and an upper bonding insulating layer 18, and the lower semiconductor die 20 may include a lower common top metal pattern 231, a lower common back-side pad 232, a lower common through-via 235, a lower common bonding pad 237, and a lower bonding insulating layer 28.

The upper common top metal pattern 131 may be disposed adjacent to the upper front surface 11FS of the upper body 11 of the upper semiconductor die 10. The upper common back-side pad 132 may be disposed adjacent to the upper back surface 11BS of the upper semiconductor die 10. The upper common through-via 135 may pass though the upper semiconductor die 10 to connect the upper common top metal pattern 131 to the upper common back-side pad 132. The upper common bonding pad 137 may be disposed on the upper common top metal pattern 131. The upper bonding insulating layer 18 may be disposed on the upper front surface 11FS of the upper semiconductor die 10 to surround side surfaces of the upper common bonding pad 137.

The lower common top metal patterns 231 may be disposed adjacent to the lower front surface 21FS of the lower semiconductor die 20. The lower common back-side pad 232 may be disposed adjacent to the lower back surface 21BS of the lower semiconductor die 20. The lower common through-via 235 may pass through the lower semiconductor die 20 and connect the lower common top metal pattern 231 to the lower common back-side pad 232. The lower common bonding pad 237 may be disposed on the lower common top metal pattern 231. The lower bonding insulating layer 28 may be disposed on the lower front surface 21FS to surround side surfaces of the lower common bonding pad 237.

The upper common bonding pad 137 of the upper semiconductor die 10 and the lower common bonding pad 237 of the lower semiconductor die 20 may be directly in contact and be bonded to each other. The upper bonding insulating layer 18 of the upper semiconductor die 10 and the lower bonding insulating layer 28 of the lower semiconductor die 20 may be directly in contact and bonded to each other. The upper bonding insulating layer 18 and the lower bonding insulating layer 28 may include silicon oxide.

The upper common top metal pattern 131, the upper common back-side pad 132, the upper common through-via 135, and the upper common bonding pad 137 of the upper semiconductor die 10, and the lower common top metal pattern 231, the lower common back-side pad 232, the lower common through-via 235, and the lower common bonding pad 237 of the lower semiconductor die 20 may be commonly electrically connected to both upper and lower electrical circuits in the upper and lower semiconductor dies 10 and 20.

Referring to FIGS. 2A and 2C, the upper semiconductor die 10 may include a first upper top metal pattern 151, a first upper back-side pad 152, a first upper through-via 155, and a first upper bonding pad 157 disposed in the first upper bonding pad region 15, a second upper top metal pattern 161, a second upper back-side pad 162, a second upper through-via 165, and a second upper bonding pad 167 disposed in the second upper bonding pad region 16. The lower semiconductor die 20 may include a first lower top metal pattern 251 and a first lower bonding pad 257 disposed in the first lower bonding pad region 25, a second lower top metal pattern 261 and a second lower bonding pad 267 disposed in the second lower bonding pad region 26. The lower semiconductor die 20 may not include a lower through-via and a lower back-side pad to be connected to the first lower top metal pattern 251. In addition, the lower semiconductor die 20 may not include a lower through-via and a lower back-side pad to be connected to the second lower top metal pattern 261.

The first and second upper top metal patterns 151 and 161 may be disposed adjacent to the upper front surface 11FS of the upper 1s semiconductor die 10. The first and second upper back-side pads 152 and 162 may be disposed adjacent to the upper back surface 11BS of the upper semiconductor die 10. The first upper through-via 155 may electrically connect the first upper top metal pattern 151 to the first upper back-side pad 152 passing through the upper semiconductor die 10, and the second upper through-via 165 may electrically connect the second upper top metal pattern 161 to the second upper back-side pad 162 passing through the upper semiconductor die 10. The first upper bonding pad 157 may be disposed on the first upper top metal pattern 151, and the second upper bonding pad 167 may be disposed on the second upper top metal pattern 161. The upper bonding insulating layer 18 may be disposed on the upper front surface 11FS of the upper semiconductor die 10 to surround side surfaces of the first and second upper bonding pads 157 and 167.

The first and second lower top metal patterns 251 and 261 may be disposed adjacent to the lower front surface 21FS of the lower semiconductor die 20. The first lower bonding pad 257 may be disposed on the second upper top metal pattern 251, and the second lower bonding pad 267 may be disposed on the second lower top metal pattern 261. The lower bonding insulating layer 28 may be disposed on the lower front surface 21FS of the lower semiconductor die 20 to surround side surfaces of the first and second lower bonding pads 257 and 267.

The first upper bonding pad region 15 of the upper semiconductor die 10 and the second lower bonding pad region 26 of the lower semiconductor die 20 may be vertically aligned with each other, and the second upper bonding pad region 16 of the upper semiconductor die 10 and the first lower bonding pad region 25 of the lower semiconductor die 20 may be vertically aligned with each other. For example, the first upper bonding pad 157 in the first upper bonding pad region 15 of the upper semiconductor die 10 and the second lower bonding pad 267 in the second lower bonding pad region 26 of and the lower semiconductor die 20 may be vertically aligned to be directly contacted and bonded to each other, and the second upper bonding pad 167 in the second upper bonding pad region 16 of the upper semiconductor die 10 and the first lower bonding pad 257 in the first lower bonding pad region 25 of the lower semiconductor die 20 may be vertically aligned to be directly contacted and bonded to each other. Accordingly, the conductive elements 151, 152, 155, and 157 in the first upper bonding pad region 15 of the upper semiconductor die 10 and the conductive elements 261 and 267 in the second lower bonding pad region of the lower semiconductor die 20 may be electrically connected to each other. The conductive elements 162, 162, 165, and 167 in the second upper bonding pad region 16 of the upper semiconductor die 10 and the conducive elements 251 and 257 in the first lower bonding pad region 25 of the lower semiconductor die 20 may be electrically connected to each other.

In one embodiment, any one of the first lower top metal pattern 251 and the second lower top metal pattern 261 may be electrically connected to a lower electrical circuit in the lower semiconductor die 20, and the other one of the first lower top metal pattern 251 and the second lower top metal pattern 261 may not be electrically connected to the lower electrical circuit in the lower semiconductor die 20. The first one of the first lower top metal pattern 251 and the second lower top metal pattern 261 may not be electrically connected to the electrical circuit in the upper semiconductor die 10, and the second one of the first lower top metal pattern 251 and the other of the second lower top metal pattern 261 may be electrically connected to the electrical circuit in the lower semiconductor die 10.

In one embodiment, any one of the first top metal pattern 151 and the second upper top metal pattern 161 may be electrically connected to an upper electrical circuit in the upper semiconductor die 10, and the other one the first upper top metal pattern 151 and the second upper top metal pattern 161 may not be connected to the upper electrical circuit in the upper semiconductor die 10. The one of the first upper top metal pattern 151 and the second upper top metal pattern 161 may not be electrically connected to the lower electrical circuit in the lower semiconductor die 20, and the other one of the first upper top metal pattern 151 and the second upper top metal pattern 161 may be electrically connected to the lower electrical circuit in the lower semiconductor die 20.

That is, the one of the first upper top metal pattern 151 and the second upper top metal pattern 161 may be electrically exclusively connected to the upper semiconductor die 10, and the other one of the first upper top metal pattern 151 and the upper top metal pattern 161 may be electrically exclusively connected to the lower semiconductor die 20. In one embodiment, the first upper top metal pattern 151 may selectively communicate with one of the upper semiconductor die 10 and the lower semiconductor die 20, and the second upper top metal pattern 161 may selectively communicate with the other one of the upper semiconductor 10 and the lower semiconductor die 20.

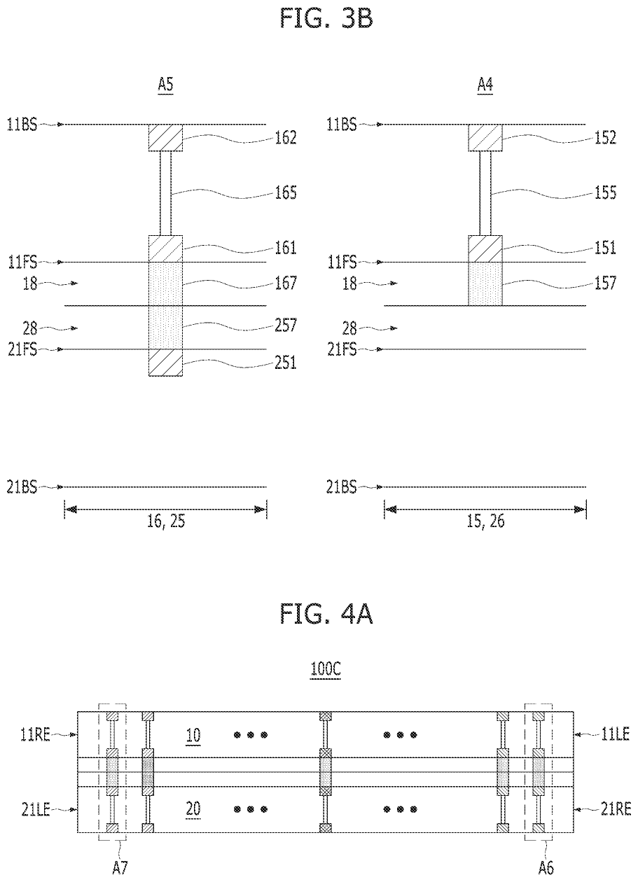

FIG. 3A is a side view schematically illustrating a semiconductor die stack 100B according to an embodiment of the present invention disclosure, and FIG. 3B is an enlarged view of the area A4 and area A5 of FIG. 3A. Referring to FIGS. 3A and 3B, a semiconductor die stack 100B according to an embodiment of the present invention disclosure may include a lower semiconductor die 20 and an upper semiconductor die 10 bonded and stacked on the lower semiconductor die 20.

The upper semiconductor die 10 may include a first upper top metal pattern 151, a first upper back-side pad 152, a first upper through-via 155, and a first bonding pad 157 disposed in a first upper bonding pad region 15, a second top metal pattern 161, a second upper back-side pad 162, a second upper through-via 155, and a first upper bonding pad 157 disposed in a second upper bonding pad region 16. The lower semiconductor die 20 may include a first lower top metal pattern 251 and a first lower bonding pad 257 disposed in a first lower bonding pad region 25. Compared to the connection structure of FIG. 2C, any conductive elements to be electrically connected to the first upper top metal pattern 151 or the first upper bonding pad 157 may not be disposed in the second lower bonding pad region 26.

In one embodiment, the first upper bonding pad 157 in the first upper bonding pad region 15 of the upper semiconductor die 10 may not be formed.

In the present embodiment, the second upper top metal pattern 161 in the second upper bonding pad region 16 of the upper semiconductor die 10 may not be electrically connected to the upper electrical circuit in the upper semiconductor die 10. That is, the second upper top metal pattern 161, the second upper back-side pad 162, the second upper through-via 165, and the second upper bonding pad 167 in the second upper bonding pad region 16 may not be electrically connected to the upper electrical circuit in the upper semiconductor die 10, and electrically connected to the first lower top metal pattern 251 and the first lower bonding pad 257 in the first lower bonding pad region of the lower semiconductor die 20. That is, the conductive elements 161, 162, 165, and 167 in the second upper bonding pad region 16 may be electrically connected to the lower electrical circuit in the lower semiconductor die 20. Compared to FIG. 2C, since there are no conductive elements in the second lower bonding pad region 26 of the lower semiconductor die 20, the conductive elements 151, 152, 155, and 157 in the first upper bonding pad region 15 of the upper semiconductor die 10 may not be electrically connected to the lower electrical circuits in the lower semiconductor die 20.

That is, the conductive elements 151, 152, 155, and 157 in the first upper bonding pad region 15 of the upper semiconductor die 10 may be electrically connected to the upper electrical circuit in the upper semiconductor die 10, and the conductive elements 161, 162, 165, and 167 in the second upper bonding pad region 16 of the upper semiconductor die 10 may be electrically connected to the lower electrical circuit in the lower semiconductor die 20 through the conductive elements 251 an 257 in the first lower bonding pad region of the lower semiconductor die 20. The other reference numerals not described can be understood with reference to FIGS. 2A to 2C.

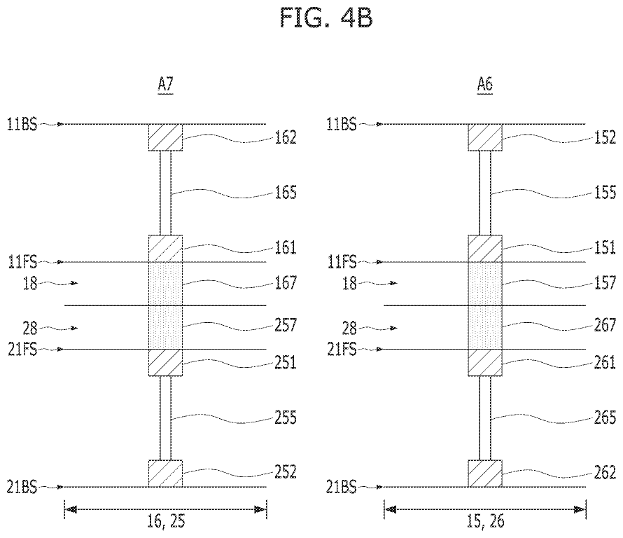

FIG. 4A is a side view schematically illustrating a semiconductor die stack 100C according to an embodiment of the present invention disclosure, and FIG. 4B is an enlarged view of the area A6 and area A7 of FIG. 4A. Referring to FIGS. 4A and 4B, a semiconductor die stack 100C according to an embodiment of the present invention disclosure may include a lower semiconductor die 20 and an upper semiconductor die 10 bonded and stacked on the lower semiconductor die 20.

The upper semiconductor die 10 may include a first upper top metal pattern 151, a first upper back-side pad 152, a first upper through-via 155, and a first upper bonding pad 157 disposed in a first upper bonding pad region 15, and a second upper top metal pattern 161, a second upper back-side pad 162, a second upper back-side pad 162, a second upper through-via 165, and a second bonding pad 167 in a second upper bonding pad region 16. The lower semiconductor die may include a first lower top metal pattern 251, a first lower back-side pad 252, a first lower through-via 255, and a first lower bonding pad 257 disposed in a lower bonding pad region 25, and a second lower top metal pattern 261, a second lower back-side pad 262, a second lower through-via 265, and a second lower bonding pads 267 disposed in a second lower bonding pad region 26.

The first and second lower back-side pads 252 and 262 may be disposed adjacent to the lower back-side 21BS of the lower semiconductor die 20. The first lower through-via 255 may pass through the lower semiconductor die 20 and electrically connect the first lower top metal pattern 251 to the first lower back-side pad 252, and the second lower through-via 265 may pass through the lower semiconductor die 20 and electrically connect the second lower top metal pattern 261 to the second lower back-side pad 262. The other reference numerals not described and the inventive concept of the embodiment can be understood with reference to FIGS. 2A to 2C and 3A and 3B.

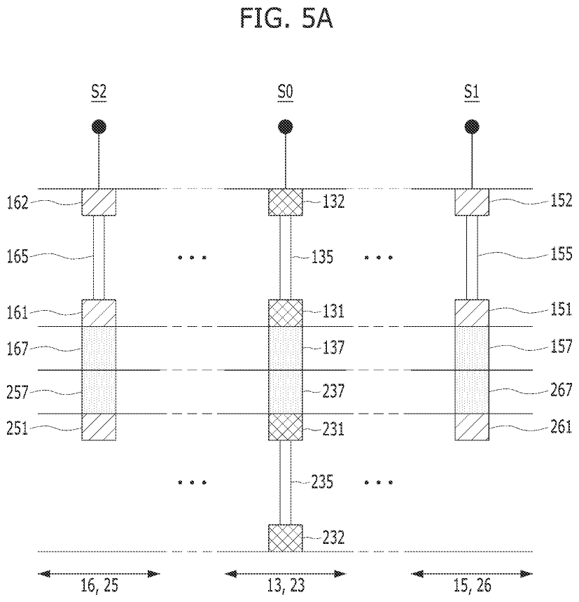

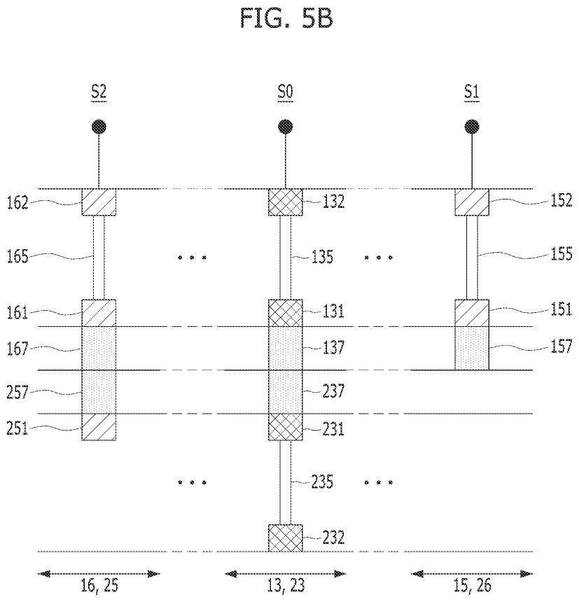

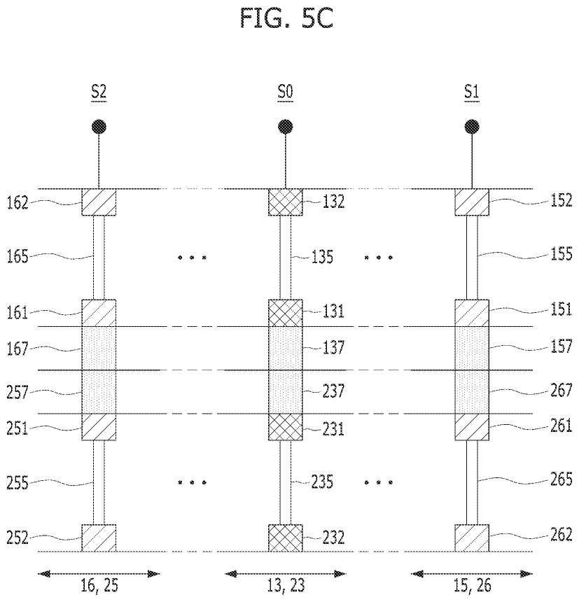

FIGS. 5A to 5C are views illustrating a method of testing the upper semiconductor die 10 and the lower semiconductor die 20 of the semiconductor die stacks 100A-100C according to an embodiment of the present invention disclosure. Referring to FIGS. 5A to 5C, a method of testing the semiconductor die stacks 100A-100C according to an embodiment of the present invention disclosure may include preparing the semiconductor die stacks 100A-100C each including the upper semiconductor die 10 and the lower semiconductor die 20, providing a common signal S0 to the conductive elements 131, 132, 135, and 137 in the upper common bonding pad region 13 and the conductive elements 231, 232, 235, and 237 in the lower common bonding pad region 23, providing a first signal S1 to the conductive elements 151, 152, 155, and 157 in the first upper bonding pad region 15 and the conductive elements 261, 262, 265, and 267 in the second lower bonding pad region 26, and providing a second signal S2 to the conductive elements 161, 162, 165, and 167 in the second upper bonding pad region 16 and the conductive elements 251, 252, 255, and 257 in the first lower bonding pad region 25.

The common signal S0 may be commonly provided to the upper semiconductor die 10 and the lower semiconductor die 20. For example, a common signal S0 may include a command signal CMD, an address signal ADDR, a data signal DQ, and a power signal PWR. The first signal S1 may be provided to the upper semiconductor die 10. The first signal S1 may include a first chip selection signal CS1 for selecting the upper semiconductor die 10. The first signal S1 may further include various reference voltage signals VDDs, VSS, and VPPE. The second signal S2 may be provided to the lower semiconductor die 20. The second signal S2 may include a second chip selection signal CS2 for selecting the lower semiconductor die 20. The second signal S2 may also further include various reference voltage signals VDDs, VSS, and VPPE. The upper semiconductor die 10 may be selected and activated by the first chip selection signal CS1, and the upper semiconductor die 10 may be tested by the common signal S0 and the first signal S1. The lower semiconductor die 20 may be selected and activated by the second chip selection signal CS2, and the lower semiconductor die 10 may be tested by the common signal S0 and the second signal S2. The first signal S1 and the second signal S2 can be provided exclusively. That is, the first signal S1 and the second signal S2 may not be simultaneously provided to the upper semiconductor die 10 and the lower semiconductor die 20. Thus, the upper semiconductor die 10 and the lower semiconductor die may be selected and activated independently and can be tested independently.

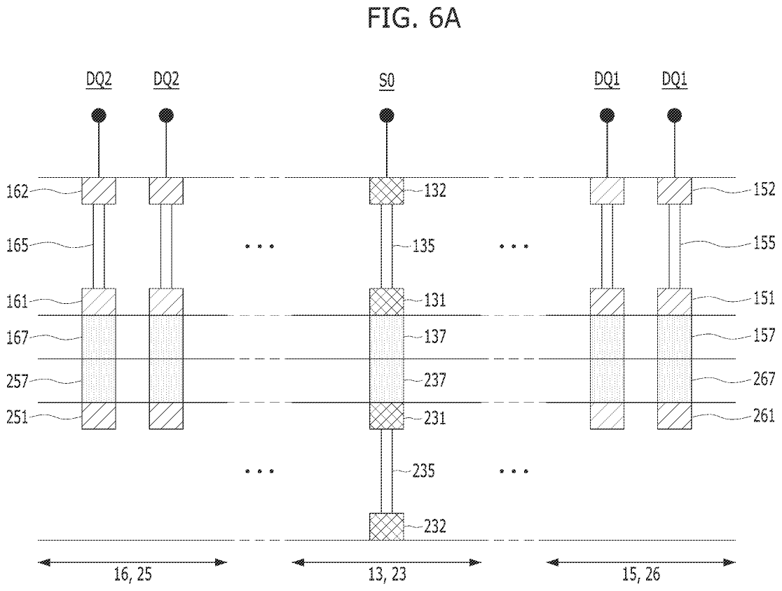

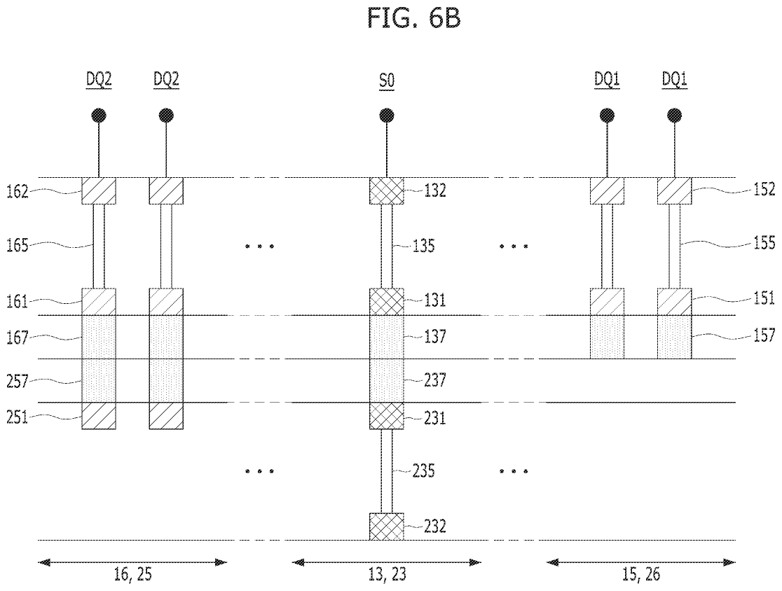

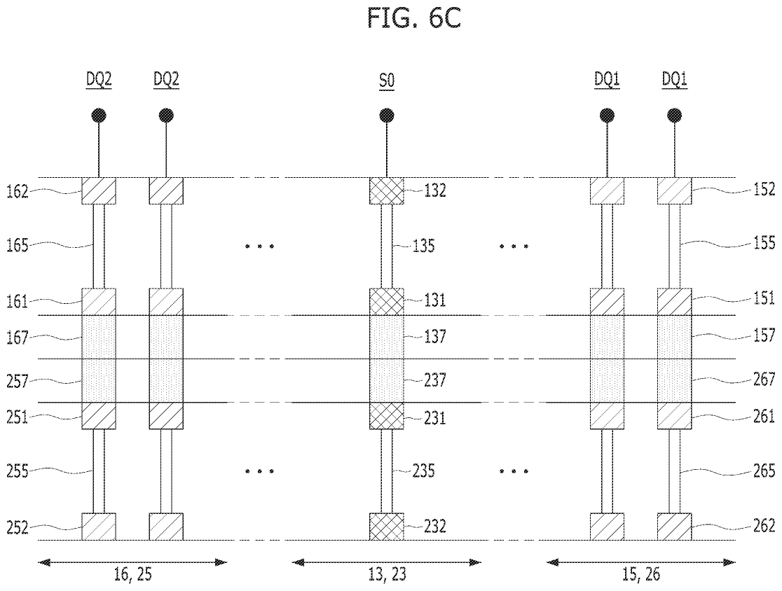

FIGS. 6A to 6C are views illustrating a method of testing the upper semiconductor die 10 and lower semiconductor die 20 of the semiconductor die stacks 100A-100C according to an embodiment of the present invention disclosure. Referring to FIGS. 6A to 6C, a method of testing the upper semiconductor die 10 and the lower semiconductor die 20 of the semiconductor die stacks 100A-100C according to an embodiment of the present invention disclosure may include preparing the semiconductor die stacks 100A-100C including the lower semiconductor die 20 and the upper semiconductor die 10 stacked on the lower semiconductor die 20, providing a common signal S0 to the conductive elements 131, 132, 135, and 137 in the upper common bonding pad region 13 and the conductive elements 231, 232, 235, and 237 in the lower common bonding pad region 23, providing a first data signal DQ1 to the conductive elements 151, 152, 155, and 157 in the first upper bonding pad region 15 and the conductive elements 261, 262, 265, and 267 in the second lower bonding pad region 26, and providing a second data signal DQ2 to the conductive elements 161, 162, 165, and 167 in the second upper bonding pad region 16 and the conductive elements 251, 252, 255, and 257 in the first lower bonding pad region 25. The first data signal DQ1 may transfer data of the upper semiconductor die 10. The second data signal DQ2 may transfer data of the lower semiconductor die 20. As described above, the conductive elements 151, 152, 155, and 157 in the first upper bonding pad region in which the first data signal DQ1 is provided may not be electrically connected to the lower electrical circuit in the lower semiconductor die 20. The conductive elements 161, 162, 165, and 167 in the second upper bonding pad region 16 in which the second data signal DQ2 is provided may not be electrically connected to the upper electrical circuit in the upper semiconductor die 10. The conductive elements 251 and 257 in the first lower bonding pad region 25 may be electrically connected to the lower electrical circuits in the lower semiconductor die 20.

In the present embodiment, the first chip selection signal CS1 for selecting the upper semiconductor die 10 and the second chip selection signal CS2 for selecting the lower semiconductor die 20 may be included in the common signal S0. For example, the upper semiconductor die 10 and the lower semiconductor die 20 may be selected and activated at the same time, but the data may be written and read out through different bonding pads, respectively.

In another embodiment, the first chip selection signal CS1 may be provided to the conductive elements 151, 152, 155, and 157 in the first upper bonding pad region 15, and the second chip selection signal CS2 may be provided to the conductive elements 161, 162, 165, and 167 of the second upper bonding pad region 16 may be provided.

Referring to FIGS. 5A to 5C and 6A to 6C, the conductive elements 151, 152, 155, and 157 in the first upper bonding pad region of the upper semiconductor die 10 and the conductive elements 261, 262, 265, and 267 in the second lower bonding pad region 26 of the lower semiconductor die 20 may be used exclusively to test the upper semiconductor die 10, and the conductive elements 161, 162, 165, and 167 in the second upper bonding pad region 16 of the upper semiconductor die 10 and the conductive elements 251, 252, 255, and 257 in the first lower bonding pad region 25 of the lower semiconductor die 20 may be used exclusively to test the lower semiconductor die 20.

According to the various embodiments of the present invention disclosure, two stacked semiconductor dies 10 and 20 of the semiconductor die stacks 100A-100C can be tested at the same time. That is, the upper semiconductor die 10 and the lower semiconductor die 20 may be tested simultaneously after bonded and stacked. Therefore, the test process for testing the semiconductor dies 10 and can be carried out fast. In addition, errors occurred in the bonding process can be easily detected.

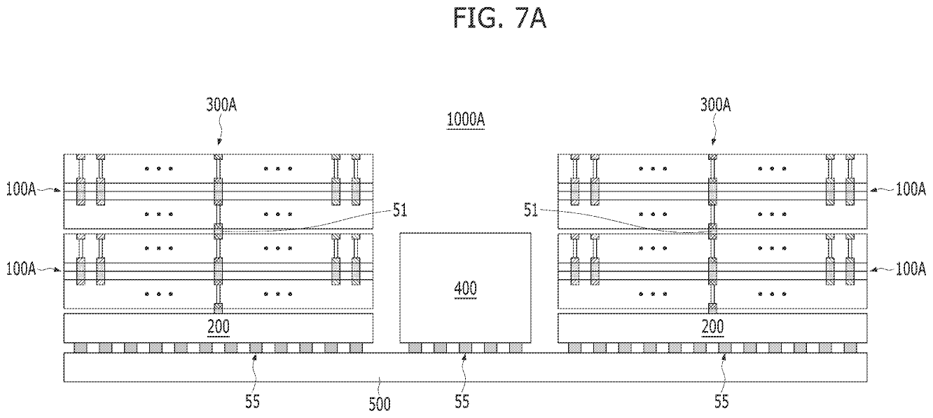

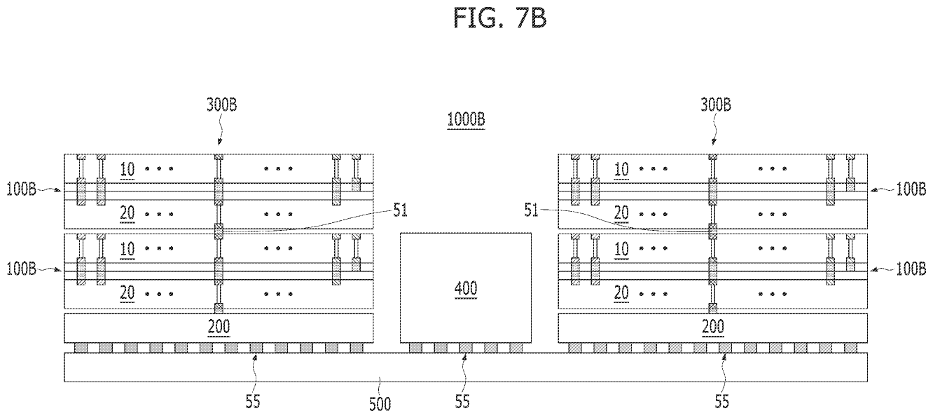

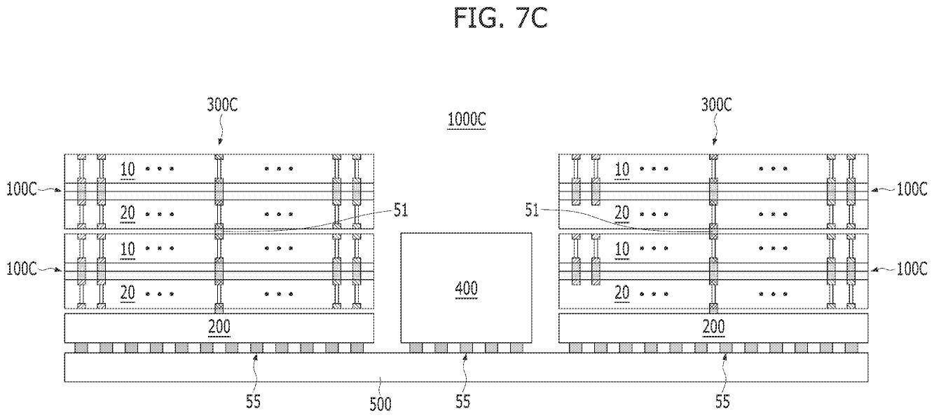

FIGS. 7A to 7C are views schematically illustrating high bandwidth memories 1000A-1000C according to embodiments of the present invention disclosure. Referring to FIGS. 7A to 7C, high-bandwidth memories 1000A-1000C according to embodiments of the disclosure may include memory stacks 300A-300C and a processing unit 400 on an interposer substrate 500, respectively. Each of the memory stacks 300A-300B may include a plurality of semiconductor die stacks 100A-100C. The memory stacks 300A-300C and the processing unit 400 may be bonded to be electrically connected to the interposer substrate 500 through interposer bumps 55. The interposer bumps 55 may include solder materials or metals. The interposer substrate 500 may include internal interconnections. The memory stacks 300A-300C and processing unit 400 may be electrically connected to each other through the internal interconnections of the interposer substrate 500.

The memory stacks 300A-300C may include the semiconductor die stacks 100A-100C stacked on a base die 200. The base die 200 and the semiconductor die stacks 100A-100C may be electrically connected to each other through inter-stack bumps 51.

The inter-stack bumps 51 may electrically connect the upper common back-side pads 132 of the upper semiconductor die 10 of each of the semiconductor die stacks 100A-100C and the lower common back-side pads 232 of the lower semiconductor die 20 of each of the semiconductor die stacks 100A-100C. Accordingly, the corresponding upper common back-side pad 132 in the upper bonding pad region 13 of the upper semiconductor die 10 and the corresponding lower back-side common bonding pad 232 in the lower common bonding pad region 23 of the lower semiconductor die 20 may be electrically connected each other through the inter-stack bumps 51. The inter-stack bumps 51 may not be formed on the first upper back-side pad 152 in the first upper bonding pad region 15 and the second upper back-side pad 162 in the second upper bonding pad region 16 of the upper semiconductor die 10 of each of the semiconductor stacks 100A-100C, and on the first lower back-side pad 252 in the first lower bonding pad region 25 and the second lower back-side pad 262 in the second back-side pad region 26 of the lower semiconductor die 20 of each of the semiconductor stacks 100A-100C.

The conductive elements 151, 152, 155, 157, 161, 162, 165, and 167 in the first and second upper bonding pad regions 15 and 16 of the upper semiconductor die 10 of the semiconductor die stacks 100A-100C disposed at a lower position of the memory stacks 300A-300C and the conductive elements 251, 252, 255, 257, 261, 262, 265, and 267 in the first and second lower bonding pad regions 25 and 26 of the lower semiconductor die 20 of the semiconductor die stacks 100A-100C disposed at an upper position of the memory stacks 300A-300C may not be electrically and physically connected to each other.

Accordingly, in each of the memory stack 300A-300C, the conductive elements 151, 152, 155, 157 in the first upper bonding pad region 15 of the upper semiconductor die 10 of each of the semiconductor stacks 100A-100C disposed at the lower position and the conductive elements 261, 262, 265, and 267 in the second lower bonding pad region 26 of the lower semiconductor die 20 of each of the semiconductor die stacks 100A-100C disposed at the upper position may be vertically aligned and may not be electrically connected with each other, respectively, and the conductive elements 161, 162, 165, 167 in the second upper bonding pad region 16 of the upper semiconductor die 10 of each of the semiconductor stacks 100A-100C disposed at the lower position and the conductive elements 251, 252, 255, and 257 in the first lower bonding pad region 25 of the lower semiconductor die 20 of each of the semiconductor die stacks 100A-100C disposed at the upper position may be vertically aligned and may not be electrically connected with each other, respectively.

According to embodiments of the present invention disclosure, the semiconductor dies include asymmetrically arrayed bonding pads, the semiconductor die stack includes the semiconductor dies bonded in the face-to-face form, accordingly, the stacked semiconductor dies can be tested at the same time.

According to the embodiments of the present invention disclosure, since the bonded semiconductor die can be tested at the same time, the test process for testing the semiconductor dies can be carried out quickly.

According to the embodiments of the present invention disclosure, an error generated in a bonding process may be detected because the test process for testing the semiconductor dies after performing the bonding process.

While the present invention has been described with respect to the specific embodiments, it will be apparent to those skilled in the art that various changes and modifications may be made without departing from the spirit and scope of the invention as defined in the following claims.

What is claimed is:

1. A semiconductor die stack comprising:
a lower semiconductor die and an upper semiconductor die stacked in a face-to-face form,
wherein the upper semiconductor die includes:
a first upper bonding pad disposed in a first upper bonding pad region adjacent to a first edge side of the upper semiconductor die; and
a second upper bonding pad disposed in a second upper bonding pad region adjacent to a second edge side of the upper semiconductor die, the first edge side and the second edge side of the upper semiconductor die being opposite to each other, wherein the lower semiconductor die includes:
a first lower bonding pad disposed in a first lower bonding pad region adjacent to a first edge side of the lower semiconductor die; and
a second lower bonding pad disposed in a second lower bonding pad region adjacent to a second edge side of the lower semiconductor die, the first edge side and the second edge side of the lower semiconductor die being opposite to each other,
wherein the second upper bonding pad and the first lower bonding pad are vertically aligned and directly bonded to each other, and
wherein the second upper bonding pad and the first lower bonding pad are not electrically connected to an upper electrical circuit in the upper semiconductor die, and electrically connected to a lower electrical circuit in the lower semiconductor die.

2. The semiconductor die stack of claim 1, wherein:
the upper semiconductor die further comprises an upper common pad region disposed in a central region of a front surface of the upper semiconductor die,
the lower semiconductor die further comprises a lower common pad region disposed in a central region of a front surface of the lower semiconductor die, and
an upper common pad in the upper common pad region and a lower common pad in the lower common pad region are bonded to each other.

3. The semiconductor die stack of claim 2,
wherein the upper semiconductor die further comprises an upper top metal pattern, an upper common back-side pad, and an upper common through-via disposed to be vertically aligned with the upper common pad, and
wherein the lower semiconductor die further comprises a lower top metal pattern, a lower common back-side pad, and a lower common through-via disposed to be vertically aligned with the lower common pad.

4. The semiconductor die stack of claim 2, wherein the upper common pad and the lower common pad are test pads.

5. The semiconductor die stack of claim 1, wherein the upper semiconductor die further includes:
a first upper top metal pattern, a first upper back-side pad, and a first upper through-via to be vertically aligned with the first bonding pad in the first upper bonding pad region; and
a second upper top metal pattern, a second upper back-side pad, and a second upper through-via to be vertically aligned with the second bonding pad in the second upper bonding pad region.

6. The semiconductor die stack of claim 1, wherein the first upper bonding pad is electrically connected to an upper electrical circuit in the upper semiconductor die and is not electrically connected to a lower electrical circuit in the lower semiconductor die.

7. The semiconductor die stack of claim 6, wherein the first upper bonding pad and the second lower bonding pad are vertically aligned to be directly bonded with each other.

8. The semiconductor die stack of claim 1, wherein:
the upper semiconductor die further comprises an upper bonding insulating layer disposed on the front surface of the upper semiconductor die, the upper bonding insulating layer surrounding side surfaces of the first and second upper bonding pads,
the lower semiconductor die further comprises a lower bonding insulating layer disposed on the front surface of the lower semiconductor die, the lower bonding insulating layer surrounding side surfaces of the first and second lower bonding pads, and
the upper bonding insulating layer and the lower bonding insulating layer are directly bonded with each other.

9. The semiconductor die stack of claim 1,
wherein the first edge side of the upper semiconductor die and the second edge side of the lower semiconductor die are vertically aligned with each other, and
wherein the second edge side of the upper semiconductor die and the first edge side of the lower semiconductor die are vertically aligned with each other.

10. The semiconductor die stack of claim 1, wherein the first and second upper bonding pads and the first and second lower bonding pads are test pads.

11. A memory stack comprising:
a plurality of semiconductor die stacks and inter-stack bumps between the semiconductor die stacks,
wherein each of the plurality of semiconductor die stacks includes an upper semiconductor die and a lower semiconductor die bonded in a face-to-face form,
wherein the upper semiconductor die includes:
an upper common pad disposed in an upper common pad region disposed in a central region of a front surface of the upper semiconductor die;
a first upper bonding pad disposed in a first upper bonding pad region adjacent to a first edge side of the upper semiconductor die; and
a second upper bonding pad disposed in a second upper bonding pad region adjacent to a second edge side of the upper semiconductor die,
wherein the lower semiconductor die includes:
a lower common pad disposed in a lower common pad region disposed in a central region of a front surface of the lower semiconductor die;
a first lower bonding pad disposed in a first lower bonding pad region adjacent to a first edge side of the lower semiconductor die; and
a second lower bonding pad disposed in a second lower bonding pad region adjacent to a second edge side of the lower semiconductor die,
wherein:
the upper common pad and the lower common pad are vertically aligned to be directly bonded with each other,
the first upper bonding pad and the second lower bonding pad are vertically aligned to be directly bonded with other,
the second upper bonding pad and the first lower bonding pad are vertically aligned to be directly bonded with each other,
the upper common pad of a lower semiconductor die stack disposed at a lower position of the semiconductor die stacks and the lower common pad of an upper semiconductor die stack disposed at an upper position of the semiconductor die stacks are electrically connected with each other through an inter-stack bump, and
the first upper bonding pad of the lower semiconductor die stack disposed at the lower position of the semiconductor die stacks and the second lower bonding pad of the upper semiconductor die tack disposed at the upper position of the semiconductor die stacks are not electrically connected with each other.

12. The memory stack of claim 11, wherein the inter-stack bump is not disposed between the first upper bonding pad of the lower semiconductor die stack disposed at the lower position of the semiconductor die stacks and the second lower bonding pad of the upper semiconductor die stack disposed at the upper position of the semiconductor die stacks.

13. The memory stack of claim 11, wherein the second upper bonding pad of the lower semiconductor die stack disposed at the lower position of the semiconductor die stacks and the first lower bonding pad of the upper semiconductor die stack disposed at the upper position of the semiconductor die stacks are not electrically connected with each other.

14. The memory stack of claim 13, wherein the inter-stack bump is not disposed between the second upper bonding pad of the lower semiconductor die stack disposed at the lower position of the semiconductor die stacks and the first lower bonding pad of the upper semiconductor die stack disposed at the upper position of the semiconductor die stacks.

15. The memory stack of claim 11,
wherein the first edge side of the upper semiconductor die and the second edge side of the lower semiconductor die are vertically aligned with each other, and
wherein the second edge side of the upper semiconductor die and the first edge side of the lower semiconductor die are vertically aligned with each other.

16. A high bandwidth memory comprising:
an interposer; and
a plurality of memory stacks and a processing unit mounted on the interposer,
wherein each of the plurality of memory stacks includes:
a base die; and
a semiconductor die stack stacked on the base die,
wherein the semiconductor die stack includes an upper semiconductor die and a lower semiconductor die bonded in a face-to-face form,
wherein the upper semiconductor die includes:
a first upper bonding pad disposed in a first upper bonding pad region adjacent to a first edge side of the upper semiconductor die; and
a second upper bonding pad disposed in a second upper bonding pad region adjacent to a second edge side of the upper semiconductor die,
wherein the lower semiconductor die includes:
a first lower bonding pad disposed in a first lower bonding pad region adjacent to a first edge side of the lower semiconductor die; and
a second lower bonding pad disposed in a second lower bonding pad region adjacent to a second edge side of the lower semiconductor die,
wherein:
the first upper bonding pad and the second lower bonding pad are vertically aligned to be directly bonded with each other,
the second upper bonding pad and the first lower bonding pad are vertically aligned to be directly bonded with each other,
the first upper bonding pad and the second lower bonding pad are electrically connected to an upper electrical circuit in the upper semiconductor die, and are not electrically connected to a lower electrical circuit in the lower semiconductor die, and
the second upper bonding pad and the first lower bonding pad are not electrically connected to the upper electrical circuit in the upper semiconductor die and are electrically connected to the lower electrical circuit in the lower semiconductor die.

17. The high bandwidth memory of claim 16, wherein:
the upper semiconductor die further includes an upper common pad in an upper common pad region,
the lower semiconductor die further includes a lower common pad in a lower common pad region, and
the upper common pad and the lower common pad are directly bonded with each other.

18. The high bandwidth memory of claim 17, further comprising an inter-stack bump between the memory stacks,
wherein the inter-stack bump electrically connects the upper common pad of the upper semiconductor die of the upper semiconductor die stack disposed at a lower position of each of the memory stacks to the lower common pad of the lower semiconductor die of the semiconductor die stack disposed at an upper position of each the memory stack.

19. The high bandwidth memory of claim 16, wherein the first and second upper bonding pads of the upper semiconductor die of the semiconductor die stack disposed at the lower position of each of the memory stacks are not electrically connected with the first and second lower bonding pads of the lower semiconductor die of the semiconductor die stack disposed at the upper position of each the memory stack.

20. The high bandwidth memory of claim 19,
wherein the inter-stack bump is not disposed between the first and second lower bonding pads of the upper semiconductor die of the semiconductor die stack disposed at the lower position of each memory stack, and
wherein the first and second lower bonding pads of the lower semiconductor die of the semiconductor die stack are disposed at the upper position of each the memory stack.
